(19) United States
(12) Patent Application Publication
(10) Pub. No.: US 2009/0105079 A1
(43) Pub. Date: Apr. 23, 2009

(54) SUPERCONDUCTIVE CONNECTION OF THE END PIECES OF TWO SUPERCONDUCTORS AND METHOD FOR MANUFACTURING THIS CONNECTION

(76) Inventor: Martino Leghissa, Wiesenthau (DE)

Correspondence Address: SCHIFF HARDIN, LLP;PATENT DEPARTMENT, 6600 SEARS TOWER, CHICAGO, IL, 60606-6473, US

(21) Appl. No.: 12/298,560

(22) PCT Filed: Apr. 5, 2007
(86) PCT No.: PCT/EP07/53354

§ 371 Date: Oct. 27, 2008

(30) Foreign Application Priority Data
May 4, 2006 (DE) 10 2006 020 829.3

(51) Int. Cl. H01B 12/00; H01L 39/24; H01R 43/00

(52) U.S. Cl. 505/220; 505/500; 174/125.1; 29/599

(57) ABSTRACT

In a superconductive connection for two end pieces of superconductors that each have a matrix of normally-conductive material and at least one superconductor lead, of superconductive material, in the matrix, and in a method for making such a superconductive connection, the respective end pieces of the conductor leads are stripped of the matrix material and are inserted into a sheath or bushing. MgB₂, as superconductive contacting material, is additionally inserted into the sheath or bushing, so as to at least partially fill regions in the sheath or bushing between the conductor leads. The cross-section of the sheath or bushing is then reduced.

### BACKGROUND OF THE INVENTION

1. Field of the Invention

The invention concerns a superconductive connection or a superconductive connection device for the end pieces of at least two superconductors that respectively have a matrix composed of normally-conductive material and at least one superconductive lead composed of superconductive material.

2. Description of the Prior Art

DE 34 13 167 A1 discloses a superconductive connection of the above type, wherein in a connection region in a sheath or bushing, the partially stripped conductor leads of the end pieces are arranged in matrix material, and superconductive contact material is provided within the sheath or bushing at least in portions of the regions between the conductor leads.

Superconductors using LTC (Low T_{c}) superconductive material or HTC (High T_{c}) superconductive material are produced as, among other things, single-core conductors or multi-filament conductors of limited conductor length. Given a corresponding conductor design of such conductors, the at least one superconductive conductor lead (or the at least one superconductive conductor filament) is embedded in a matrix of normally-conductive material. In particular given the production of superconductive devices with such superconductors (for example magnet windings), a contacting or connection of end pieces of corresponding conductors is required.

Superconductive magnet windings of the type employed in magnetic resonance tomography must be operated in a manner known as a “persistent current mode.” For this purpose, the magnet winding is shorted and the magnetic current (set once) continues to flow practically without a time limit, without a power source. However, this makes it necessary that the loop of the magnet winding through which current flows possesses practically no electrical resistance. For this, superconductive connections between individual superconductive conductors (superconductors) are also necessary. However, these superconductive connections react sensitively to magnetic fields. Namely, if the magnetic field or, respectively, the magnetic induction exceeds a certain limit value (which is typically between 1 Tesla and 2 Tesla), the connection shows an electrical resistance and thus makes a persistent current operation impossible. Given superconductive high field magnets whose magnetic induction is, for example 3 Tesla or more, this leads to problems since the connections must be attached at points in which the local magnetic field is below the cited limit value. It can even become impossible given very high fields.

A superconductive connection of the end pieces of superconductors is described in “IEEE Transactions on Applied Superconductivity”, Vol. 9, No. 2, June 1999, Pages 185 through 187, for example. To establish this connection, at the end pieces of the superconductors to be connected their filaments are uncovered (for example via etching) and are then connected with one another with the aid of a superconductive solder as a contacting material. Lead compounds—for example made from the alloy Pb27-Bi50-Sn12-Cd10 (what is known as “Wood's metal”) or similar solders based on Pb—Bi or Pb—Bi—Sn alloy are normally used as solders. All of these solder materials have an upper critical magnetic field B_{c2} of at most approximately 2 Tesla at a temperature of 4.2 K, the temperature of liquid helium at normal pressure. At fields above this critical magnetic field, they lose their superconductive properties and are therefore frequently not suitable for fashioning superconductive high field contacts.

An additional connection technique for the end pieces of two superconductors is described in “Cryogenics”, Vol. 30 (Supplement), 1990, pages 626 through 629. Here the superconductors are connected or compressed with one another directly by means of spot welding (by the application of pressure and temperature) without a contact-mediating/-facilitating intermediate material. However, the current capacity of corresponding connections is normally less than that of the conductor itself. The problem occurs that the filaments do not enter into any large-area contacts, but rather point contacts. However, the current capacity then decreases further with increasing magnetic field strengths, such that connections of this type are also not suitable for many superconductive high field contacts.

A method to produce a superconductive contact between superconductors in which the conductor leads freed from the matrix material are subjected to a pressure and temperature treatment in a sheath, with a specific powder material as an intermediate material, is disclosed in the aforementioned DE 34 13 167 A1. The powder material is selected so that superconductive material is formed with it and from the conductor precursor in this treatment. However, high temperatures of, for example, over 600° C. are thereby required. The known method is therefore very complicated and not usable in many cases.

### SUMMARY OF THE INVENTION

An object of the present invention to provide a connection or a connection device between superconductive conductors at end pieces that enables high magnetic inductions of above 1 Tesla above 2 Tesla without degradation of their current capacity, and, particularly that can be produced in a simple manner. It is also an object to provide a suitable method for simple production of such connections.

The above object is achieved in accordance with the present invention by a superconductive connection for at least two superconductors that each have a matrix composed of normally-conductive material and at least one conductor lead composed of superconductive material, wherein the connection is formed in a connection region in a sheath or bushing wherein the end pieces of the conductor leads, partially stripped of the matrix material, are arranged, with superconductive contacting material also being provided in the sheath or bushing at least in portions of the regions between the conductor leads, and wherein this superconductive contacting material is MgB₂.

The advantages of this embodiment of the superconductive connection are that the connection
makes a use possible even in high magnetic fields,
is simple and cost-effective to produce,
generally requires only one compression of the parts to be connected, such that in many cases a special temperature treatment can be foregone,
behaves robustly and stably, in particular with regard to flow spikes,
and moreover does not require a use of lead (questionable from an environmental point of view), as with known solder connections.

The use of corresponding connections in superconductive magnets enables a persistent current operation in high magnetic fields as is required for, for example, high field magnets in magnetic resonance tomographs.

Further embodiments of the connection according to the invention can also additionally exhibit the following features:
An operation at a temperature below the critical temperature of 39 K of the MgB₂ contacting material is preferably provided. The superconductive properties of the entire design within the sheath or bushing are thus ensured. The critical temperature of the superconductive material of the superconductors to be connected is thereby naturally to be taken into account, such that if necessary a cooling to a temperature lying well below 39 K can be required.
In particular, an operating temperature at the temperature of liquid helium (approximately 4.2 K) is to be provided, which enables the use of known devices of superconductive technology.
The superconductive conductor leads can thereby contain either known metallic LTC (Low T_{c}) superconductive material or known oxidic HTC (High T_{c}) superconductive material. Both material types can be electrically connected well via the MgB₂ contacting material. Naturally, conductor leads made from MgB₂ as HTC material are suitable for connection according to the invention.
The superconductive connection can in particular be associated with a superconductive magnet winding of a magnet, in particular of a system for magnetic resonance tomography. The design of magnets, in particular for high field applications, requires superconductive connections with high current capacity in the magnetic fields. The MgB₂ contacting material ensures corresponding applications.
Due to this property, the superconductive connection is particularly suitable for a superconductive magnet winding designed for a persistent current operation.

The above object also is achieved in accordance with the present invention by a method for manufacturing a superconductive connection as described above, including the steps of stripping the superconductive conductor leads at least partially of their matrix material at the end pieces thereof that are to be connected together, inserting the stripped superconductive leads into a sheath or bushing, and additionally inserting MgB₂ contact material into the sheath or bushing, and reducing the cross-section of the filled sheath or bushing.

The method is characterized in particular by its simplicity. The cross-section reduction alone advantageously suffices in many cases in order to achieve the desired connection, which also enables a use under high field conditions.

Further embodiments of the method can additionally exhibit the following features:
The MgB₂ contacting material is introduced into the sheath or bushing in powder form. A more compact design with intensive contacting between the superconductive parts and the contacting material can thus be achieved.
The filled sheath or bushing is subjected to a heat treatment after or during the cross-section reduction. The compound structure made up of the various materials can therefore be further improved with this, in particular with regard to the current capacity in high magnetic fields.
For this the heat treatment can be conducted at a temperature of below 600° C., advantageously below 250° C. A heat treatment at the relatively low temperature is to be directly realized with simple means.

### BRIEF DESCRIPTION OF THE DRAWINGS

FIG. 1 is a cross-section through a known, multi-filament superconductor of the type forming the basis for a superconductive connection according to the present invention.

FIG. 2 is a section through a first embodiment of a superconductive connection in accordance with the present invention.

FIG. 3 is a section through a second embodiment of a superconductive connection in accordance with the present invention.

### DESCRIPTION OF THE PREFERRED EMBODIMENTS

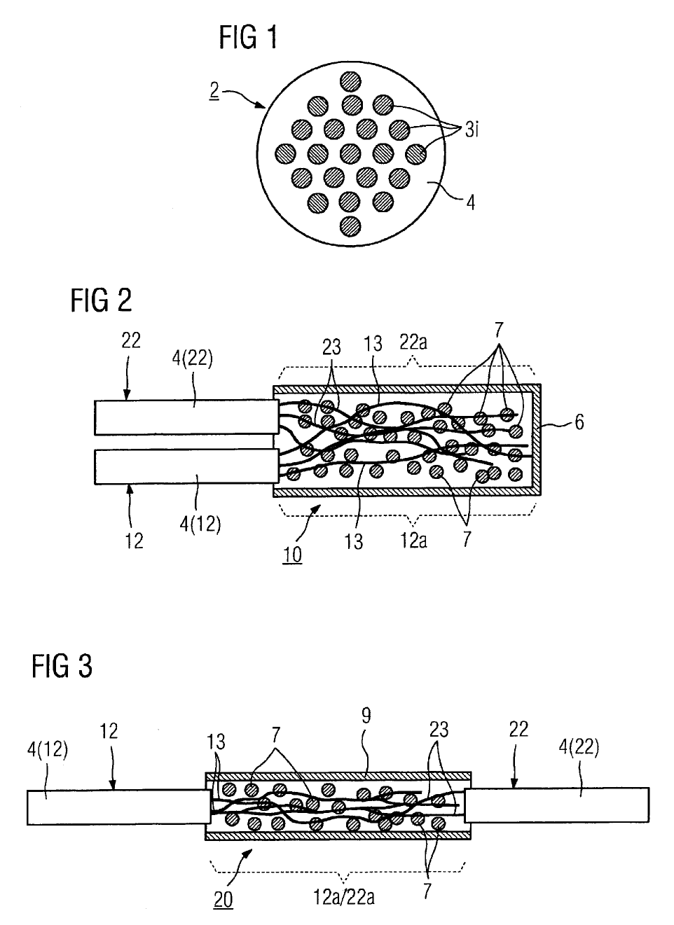

The superconductors in FIG. 1 are of a known type. They can be of the type known as single core (monocore) superconductors or (as shown in FIG. 1) the type known as multi-filament superconductors. Such a superconductor 2 has multiple superconductive conductor leads or filaments 3i that are embedded in a matrix 4 made of normally-conductive material. All known LTC or HTC superconductive materials (for example NbTi, Nb₃Sn, MgB₂, YBa₂Cu₃Oₓ or (Bi,Pb)₂Dr₂Ca₂Cu₃O_{y}) are suitable as material for the conductor leads 3i. Materials known for the matrix are either elementary (for example Cu, Ni, Ag, Fe, Wo, Al) or alloys, in particular of these elements (for example CuNi, AgMg, CuSn, CuZn or NiCr).

In order to be able to contact at least two end pieces of corresponding multi-filament superconductors or even monocore superconductors with one another according to the invention in a low-resistance manner, with a connection or, respectively, connection device, in the region of the end pieces their at least one superconductive conductor lead 3i must be at least partially uncovered, i.e. at least partially stripped of the matrix material by means of techniques known for this (for example mechanical stripping via chemical etching, in particular angled grinding). FIG. 2 shows two such superconductors 12 and 22 that can exhibit a design according to FIG. 1. Their end pieces are thereby designated with 12a or, respectively, 22a, and their corresponding completely uncovered conductor leads there are designated with 13 or, respectively, 23. The conductor leads are inserted into a bushing 6 or sheath (see FIG. 3) together with a particular contacting material 7. By a bushing or cashing, what are to be understood here are generally at least one arbitrary element accommodating and at least partially enclosing the conductor leads and the contacting material in a known manner, via which element a compaction or cross-section reduction of the parts inserted into it can be produced.

The magnesium di-boride (MgB₂) used as a contacting material according to the invention is a superconductive material with a critical temperature of approximately T_{c}=39 K (at normal pressure) and an upper critical field B_{c2} (at 4.2 K) of over 40 Tesla. It is therefore also suitable for use in high magnetic fields as they occur in high field magnets, for example, in particular of magnetic resonance tomographs. Therefore, the connection according to the invention is preferably operated using the MgB₂ contacting material at temperatures of below 39 K, for example at 4.2 K, wherein known cooling techniques (for example with liquid helium) are used. MgB₂ is commercially obtainable as a powder. Due to suitable compaction or rolling, it is in the position to carry a superconductive current even without a temperature treatment or, respectively, annealing (see “Applied Physics Letters”, Vol. 79, 2001, pages 230 through 233). Due to its relatively high critical temperature, this material is also particularly insensitive to disruptions such as, for example, flow spikes or conductor movements or unwanted increases of the operating temperature that lead to what is known as a quench.

The bushing 6 to be filled with the uncovered conductor leads 13 and 23 as well as with the powdered MgB₂ contacting material 7 advantageously is formed of a metallic material that can be easily shaped. Suitable materials for this are elementary materials such as, for example, Cu, Ni, Ag, Nb or Fe as well as alloys such as, for example, NbTi, NiCr or CuZn. In the bushing 6, the interstices between the conductor leads are filled in with the MgB₂ particles 7 (of which only a few are illustrated in FIG. 1 for clarity), in particular in the regions where the conductor leads 13 and 23 do not come to lie directly adjoining one another. The formation of the desired contact between the conductor leads is then produced via a cross-section-reducing processing, at least of the region of the conductor end pieces to be connected, as via compaction or rolling. This contacting measure can if necessary be improved by means of an annealing, advantageously at relatively low temperatures of below 250° C. Naturally, higher annealing temperatures up to 600° C. and more are also applicable as necessary (see for example “IEEE Transaction on Applied Superconductivity”, Vol. 15, No. 2, June 2005, Pages 3211 through 3214). The connection to be obtained is thus generally provided with reference character 10 in FIG. 1.

An additional embodiment of a superconductive connection (generally designated with 20) illustrated in FIG. 3 differs from the superconductive connection 10 according to FIG. 2 in that here the two superconductive conductors 12 and 22 are contacted in that their conductor leads 13 and 23 exposed in the region of their end pieces 12a and 22a are inserted in opposite directions into a sheath 9 together with the MgB₂ powder particles 7 and are compacted there.

In the embodiments of superconductive connections or, respectively, connection devices 10 or, respectively, 20 schematically presented in FIGS. 2 and 3, it was assumed that the material of the matrix 4 was entirely removed at each of the respective end pieces 12a through 22a of the superconductors 12 and 22. However, if necessary it is also possible that only one part (for example half the cross-section) of the conductor in the region of its end pieces is freed from the matrix material in mechanical or chemical ways, such that then some of the conductor leads are uncovered at one surface of the remaining structure (see EP 0 556 837 A1, for example). The surfaces of two conductor end pieces that are uncovered in this way are then joined to one another and connected with one another in the described manner with the incorporation of the MgB₂ contacting material according to the invention.

Moreover, for the representation according to FIGS. 2 and 3 it is assumed that only two superconductors 12 and 13 are electrically connected with one another at their end pieces 12a and 13a. Naturally, a greater number of end pieces (for example of three superconductors) can also be inserted into a bushing 6 or a sheath 9 and be connected with one another therein according to the invention.

Although modifications and changes may be suggested by those skilled in the art, it is the intention of the inventor to embody within the patent warranted heron all changes and modifications as reasonably and properly come within the scope of his contribution to the art.

1-12. (canceled)

13. A superconductive connection for end pieces of at least two superconductors, each of said at least two superconductors comprising a matrix of normally-conductive material and at least one superconductor lead in said matrix formed of superconductive material, said superconductive connection comprising:
a connector element selected from the group consisting of sheaths and bushings;
the conductor leads of the respective end pieces of the at least two superconductors being stripped of said matrix material and located within said connector element; and
a superconductive contacting material in said connector element that at least partially fills regions between said conductor leads in said connector element, said contacting material comprising MgB₂.

14. A superconductive connection as claimed in claim 13 operable at a temperature below a critical temperature of 39K of MgB₂.

15. A superconductive connection as claimed in claim 14 operable at a temperature of liquid helium at approximately 4.2K.

16. A superconductive connection as claimed in claim 13 wherein said conductor leads contain LTC superconductive material.

17. A superconductive connection as claimed in claim 13 wherein said conductor leads contain HTC superconductive material.

18. A superconductive connection as claimed in claim 13 wherein said at least two superconductors are superconductors of a superconducting magnet winding.

19. A superconductive connection as claimed in claim 18 wherein said magnet is a magnet of a magnetic resonance tomography system.

20. A superconductive connection as claimed in claim 18 wherein said magnet winding of said magnet of said magnetic resonance tomography system is operable in a persistent current mode.

21. A method for producing a superconductive connection of end pieces of at least two superconductors, each of said at least two superconductors having a matrix of normally-conductive material and at least one conductor lead, of superconductive material, in said matrix, said method comprising the steps of:
at least partially stripping the respective end pieces of said at least two superconductors of said matrix material, thereby forming stripped conductor leads;
inserting the stripped conductor leads into a connector element having a cross-section, said connector element being selected from the group consisting of sheaths and bushings;
also inserting MgB₂ contact material into said connector element together with the stripped conductor leads, thereby producing a filled connector element; and
reducing the cross-section of the filled connector element.

22. A method as claimed in claim 21 comprising introducing said MgB₂ contacting material into said connector element in powder form.

23. A method as claimed in claim 22 comprising exposing said filled connector element to a heat treatment after or during reducing the cross-section of said filled connector element.

24. A method as claimed in claim 23 comprising, in said heat treatment, exposing the filled connector element to a temperature below 600° C.

25. A method as claimed in claim 23 comprising, in said heat treatment, exposing the filled connector element to a temperature below 250° C.
